(19) United States
(12) Patent Application Publication
(10) Pub. No.: US 2026/0206505 A1
(43) Pub. Date: Jul. 16, 2026

(54) SEMICONDUCTOR STRUCTURE AND MANUFACTURING METHOD THEREOF

(71) Applicant: HON HAI PRECISION INDUSTRY CO., LTD., New Taipei City (TW)

(72) Inventors: Weiting LIN, New Taipei City (TW); Yi-Kai HSIAO, New Taipei City (TW); Chia-Lung HUNG, New Taipei City (TW); Wei-Cheng YU, New Taipei City (TW); Hao-Chung KUO, New Taipei City (TW)

(21) Appl. No.: 19/093,216

(22) Filed: Mar. 27, 2025

(30) Foreign Application Priority Data
Jan. 14, 2025 (TW) 114101516

(51) Int. Cl. H01L 21/04; H01L 21/311; H10D 30/01; H10D 62/10; H10D 62/60; H10D 62/832

(52) U.S. Cl. CPC H10P 30/22; H10D 30/027; H10D 62/102; H10D 62/124; H10D 62/60; H10P 50/283; H10D 62/8325

(57) ABSTRACT

A first mask is formed on the substrate. A first implantation process is performed to form a first implant region in the substrate. A first spacer and a second spacer are formed on the sidewall of the first mask. A first wet etching process is performed to remove the first spacer. A second wet etching process is performed to remove a portion of the first mask. A second implantation process is performed to form a second implant region, and the second implantation area is self-aligned with the first implant region. A third wet etching process is performed to remove the second spacer. A fourth wet etching process is performed to remove a portion of the first mask. A third implantation process is performed to form a first well region in the substrate, and the first well area is self-aligned with the second implant region.

### CROSS-REFERENCE TO RELATED APPLICATION

This application claims priority to Taiwan Application Serial Number 114101516, filed Jan. 14, 2025, which is herein incorporated by reference in its entirety.

### BACKGROUND

### Field of Invention

The present disclosure relates to a semiconductor structure and manufacturing method thereof.

### Description of Related Art

With the rapid development of power electronics technologies such as solar electronics, automotive electronics, and high-frequency and high-power density power modules in recent years, higher requirements have been placed on the power density of power electronic equipment. As the complexity of transistor components increases, exposure errors are more likely to occur during defining the component structure, thereby reducing quality.

### SUMMARY

In accordance with an aspect of the present disclosure, a method of manufacturing semiconductor structure is provided. The method includes following steps. A substrate is provided. A first mask is formed on the substrate. A first implantation process is performed with the first mask to form a first implant region in the substrate. The first spacer is removed. A first portion of the first mask is removed. A second implantation process is performed with the first mask and the second spacer to form a second implant region in the substrate, such that the second implant region is self-aligned with the first implant region. The second spacer is removed. A second portion of the first mask is removed. A third implant process is performed with the first mask to form a first well region in the substrate, such that the first well region is self-aligned with the second implant region.

According to some embodiments of the present disclosure, wherein a first wet etching process is performed using a first etchant to remove the first spacer, wherein the first spacer comprises polysilicon and the first etchant comprises tetramethylammonium hydroxide; a second wet etching process is performed using a second etchant to remove the first portion of the first mask, wherein the first mask comprises silicon nitride and the second etchant comprises phosphoric acid; a third wet etching process is performed using a third etchant to remove the second spacer, wherein the second spacer comprises silicon oxide, and the third etchant comprises hydrofluoric acid and ammonium fluoride; and a fourth wet etching process is performed using a fourth etchant to remove the second portion of the first mask, and the fourth etchant includes phosphoric acid.

According to some embodiments of the present disclosure, wherein the substrate has a heavily doped layer, a lightly doped layer located on the heavily doped layer, and a current spreading layer located within the lightly doped layer, and the first mask covers the lightly doped layer.

According to some embodiments of the present disclosure, wherein after performing the second wet etching process using the second etchant, the first mask and the second spacer together expose a portion of the first implant region and a portion of the lightly doped layer adjacent to the first implant region.

According to some embodiments of the present disclosure, wherein after performing the fourth wet etching process using the fourth etchant, the first mask exposes the first implant region, the second implant region, and a portion of the lightly doped layer adjacent to the second implanted region.

According to some embodiments of the present disclosure, the method further includes after forming the first well region, the first mask is removed, and a second mask is formed to cover the first implant region, the second implant region and the first well region, and the second mask is formed to expose the lightly doped layer.

According to some embodiments of the present disclosure, the method further includes performing a fourth implantation process with the second mask to form a transistor in the lightly doped layer of the substrate; performing a thermal annealing process to form a gate oxide layer on the substrate; and a gate is formed on the gate oxide layer.

In accordance with an aspect of the present disclosure, a method of manufacturing semiconductor structure is provided. The method includes following steps. A substrate is provided. A first mask is formed on the substrate. A first implantation process is performed with the first mask to form a first implant region in the substrate. A first spacer and a second spacer is formed on the sidewall of the first mask, wherein the first spacer is located between the first mask and the second spacer, and the first spacer and the second spacer cover the first implant region, wherein the first mask, the first spacer, and the second spacer are formed of different materials. The first spacer is removed to form a first opening, wherein a sidewall of the first implant region is aligned with a first sidewall of the first opening. A first portion of the first mask is removed to expand the first opening into a second opening. A second implantation process is performed with the first mask and the second spacer to form a second implant region in the substrate, wherein a sidewall of the second implant region is aligned with a second sidewall of the second opening. The second spacer is removed to expand the second opening into a third opening, wherein the sidewall of the second implant region is aligned with a third sidewall of the third opening. A second portion of the first mask is removed to expand the third opening into a fourth opening. A third implantation process is performed using the first mask to form a first well region in the substrate, wherein a sidewall of the first well region is aligned with a fourth sidewall of the fourth opening.

According to some embodiments of the present disclosure, wherein the substrate and the first implantation process include different dopant types.

According to some embodiments of the present disclosure, wherein the first implantation process and the second implantation process include different dopant types.

According to some embodiments of the present disclosure, wherein the first implantation process and the third implantation process include the same dopant type.

According to some embodiments of the present disclosure, wherein before performing the first implantation process, the first mask has a first thickness, and the first thickness is greater than 5 microns.

In accordance with an aspect of the present disclosure, a semiconductor structure is provided. The semiconductor structure includes a substrate, a transistor, a first well region, a first implant region, and a second implant region. The substrate has a current spreading layer. The transistor located on the current spreading layer, having a first sidewall and a second sidewall. The first well region located on the current spreading layer and respectively contacting the first sidewall and the second sidewall of the transistor, wherein a bottom surface of the first well region is lower than a top surface of the current spreading layer. The first implant region located in the first well region. The second implant region located in the first well region and between the first implant region and the transistor, the second implant region has a first sidewall and a second sidewall, wherein a first distance is between the first sidewall of the second implant region and the first sidewall of the transistor, and a second distance is between the second sidewall of the second implant region and the second sidewall of the transistor, and the first distance is equal to the second distance.

According to some embodiments of the present disclosure, wherein the substrate further comprises a heavily doped layer and a lightly doped layer. The heavily doped layer located below the current spreading layer. The lightly doped layer located between the current spreading layer and the heavily doped layer.

According to some embodiments of the present disclosure, the substrate further comprises a gate and a gate oxide. The gate located on the transistor. The gate oxide located between the transistor and the gate.

According to some embodiments of the present disclosure, wherein a bottom surface of the first implant region and a bottom surface of the second implant region are higher than the bottom surface of the first well region.

According to some embodiments of the present disclosure, wherein a top surface of the first implant region and a top surface of the second implant region and a top surface of the first well region are coplanar.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 to FIG. 15 are cross-sectional views of intermediate stages of fabricating the semiconductor structure, according to some embodiments.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

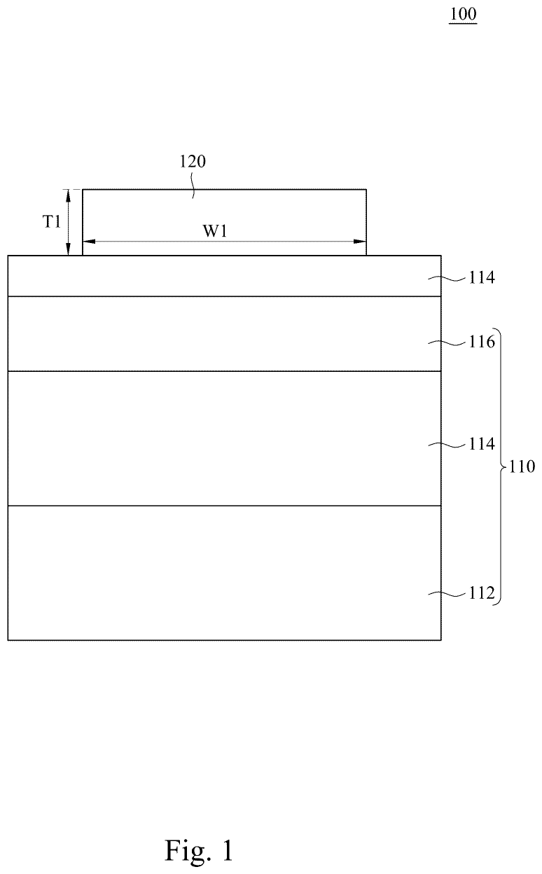

FIG. 1 to FIG. 15 are schematic cross-sectional views of various intermediate stages in the formation of a semiconductor structure 100, according to some embodiments. The semiconductor structure 100 may be applied to an integrated circuit (IC) or a part thereof, such as a logic circuit, a resistor, a capacitor, a sensor, or a storage device. It is noted that some components of the semiconductor structure 100 are not shown in FIGS. 1 to 15 to simplify the drawings, and other embodiments of the semiconductor structure 100 may include additional components.

First, referring to FIG. 1, a semiconductor structure 100 is provided. The semiconductor structure 100 includes a substrate 110 and a first mask 120 disposed on the substrate 110. The substrate 110 includes a heavily doped layer 112, a lightly doped layer 114, and a current spreading layer 116. The substrate 110 may be a semiconductor substrate, such as a silicon carbide (SiC) substrate. Since silicon carbide material is a wide energy gap semiconductor material, silicon carbide material has a higher breakdown electric field and a lower leakage current. Because silicon carbide has better thermal conductivity than silicon, it is very suitable for environments that need to operate at high temperatures, such as automotive transistors.

In some embodiments, the heavily doped layer 112 and the lightly doped layer 114 have the same first dopant type. For example, the heavily doped layer 112 and the lightly doped layer 114 have N-type doping. Alternatively, the heavily doped layer 112 and the lightly doped layer 114 have P-type doping. In some embodiments, the substrate 110 includes an N-type heavily doped layer 112 and an N-type lightly doped layer 114 epitaxially grown on the N-type heavily doped layer 112. In some other embodiments, the N-type heavily doped layer 112 and the N-type lightly doped layer 114 may also be formed by ion implantation. Next, a current spreading layer 116 is formed in the lightly doped layer 114 by ion implantation. The current spreading layer 116 is completely located in the lightly doped layer 114. In other words, a portion of the lightly doped layer 114 is located above the current spreading layer 116.

Next, the first mask 120 is formed over the substrate 110 to expose a portion of the substrate 110. In some embodiments, the first mask 120 may be silicon nitride (SiN). In some embodiments, the first mask 120 may be formed by a suitable deposition process, such as chemical vapor deposition (CVD), plasma enhanced chemical vapor deposition (PECVD), atomic layer deposition (ALD), etc. In some embodiments, the first mask 120 has a first thickness T1. In order to have good thickness uniformity and sufficient shielding, the first thickness T1 is at least 5 micrometers (mm). As shown, the first mask 120 has a first width W1.

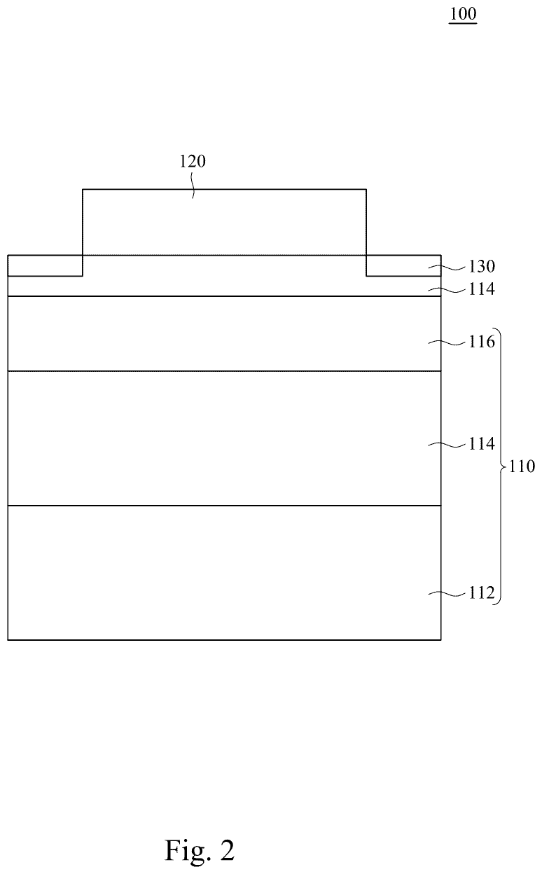

Referring to FIG. 2, a first implantation process is performed to form a first implantation region 130 in the lightly doped layer 114 of the substrate 110 through the pattern of the first mask 120. The first implant region 130 is formed in the lightly doped layer 114 of the substrate 110 that is exposed by the first mask 120. The bottom surface of the first implant region 130 is located in the lightly doped layer 114 and does not contact the current spreading layer 116. In some embodiments, the first implant region 130 has a second dopant type, wherein the second dopant type is different from the first dopant type. For example, when the lightly doped layer 114 has N-type doping, the first implant region 130 has P-type doping. For example, when the lightly doped layer 114 has P-type doping, the first implanted region 130 has N-type doping. In some embodiments, the first implant region 130 may be a P+region.

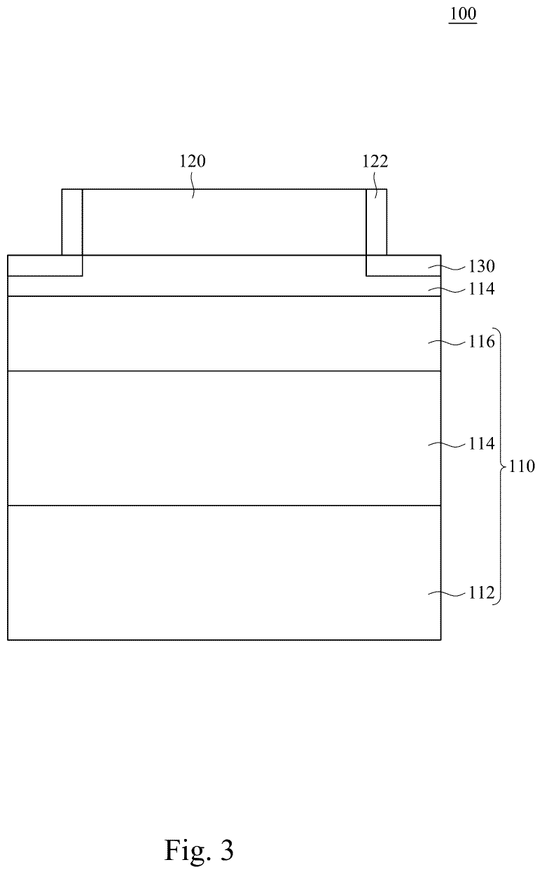

Referring to FIG. 3, a first spacer 122 is formed on the sidewall of the first mask 120. The first spacer 122 covers a portion of the top surface of the first implant region 130. In some embodiments, the first spacer 122 may be polysilicon. In some embodiments, the first spacer 122 may be formed by a suitable deposition process, such as chemical vapor deposition (CVD), plasma enhanced chemical vapor deposition (PECVD), atomic layer deposition (ALD), etc.

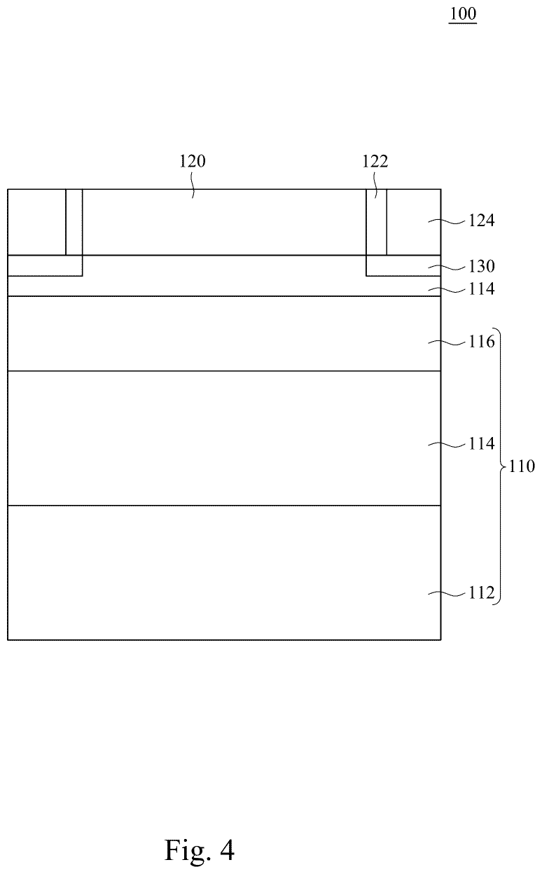

Referring to FIG. 4, a second spacer 124 is formed on the sidewalls of the first spacer 122. The second spacer 124 completely covers the top surface of the first implant region 130. In some embodiments, the second spacer 124 may be an oxide, such as silicon oxide (SiO₂). In some embodiments, materials of the first spacer 122 and the second spacer 124 may be interchanged with each other. In some embodiments, after forming the second spacer 124, a planarization process may be performed on the first mask 120, the first spacer 122, and the second spacer 124.

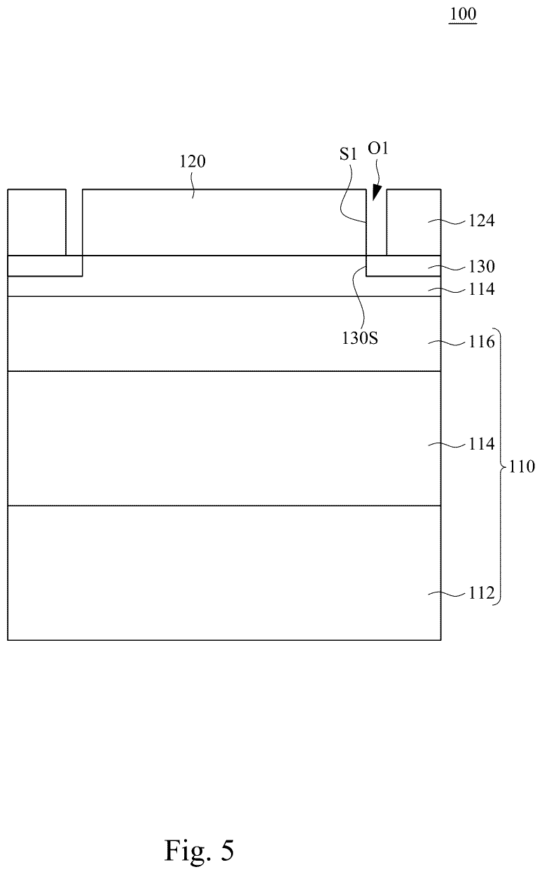

Referring to FIG. 5, a first wet etching process (or, an isotropic etching process) is performed with a first etchant to remove the first spacer 122 and expose a portion of the top surface of the first implant region 130. After the first spacer 122 is removed, a first opening O1 is formed. As shown, the first sidewall S1 of the first opening O1 is aligned with the sidewall 130S of the first implant region 130. In some embodiments, when the material of the first spacer 122 is polysilicon, the first etchant includes tetramethylammonium hydroxide (TMAH). In some embodiments, the first wet etching process is performed at a first temperature, and the first temperature is in a temperature range of 60° C. to 80° C. The first etchant has an etch rate of 50 to 400 nm per minute for the first spacer 122. Since the first mask 120, the first spacer 122, and the second spacer 124 are all formed of different materials, any etchant having a faster etching rate for the first spacer 122 may be selected to remove the first spacer 122. Removing the first spacer 122 can provide etching gaps for the subsequent wet etching process.

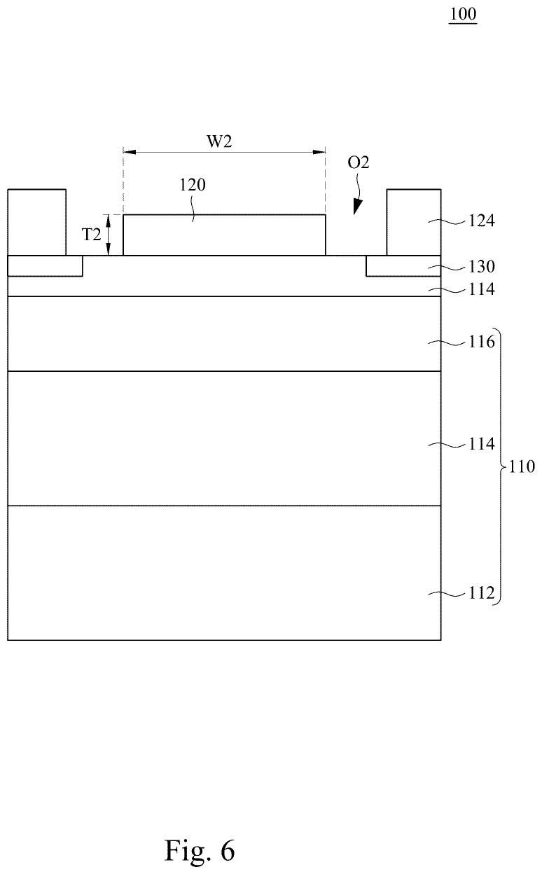

Referring to FIG. 6, a second wet etching process (or, an isotropic etching process) is performed with a second etchant to remove the first portion of the first mask 120, wherein the second etchant is different from the first etchant. After performing the second wet etching process, the first opening O1 is expanded into the second opening O2. After the second wet etching process, the first mask 120 has a second thickness T2 and a second width W2. The second thickness T2 is smaller than the first thickness T1, and the second width W2 is smaller than the first width W1. In some embodiments, the second etchant includes phosphoric acid (H₃PO₄). In some embodiments, the second wet etching process is performed at a second temperature, and the second temperature is in a temperature range of 150° C. to 180° C. The first temperature is higher than the second temperature. The second etchant has a relatively slow etching rate of 20 to 50 nm per minute for the first mask 120, so the etching condition of the first mask 120 can be accurately controlled.

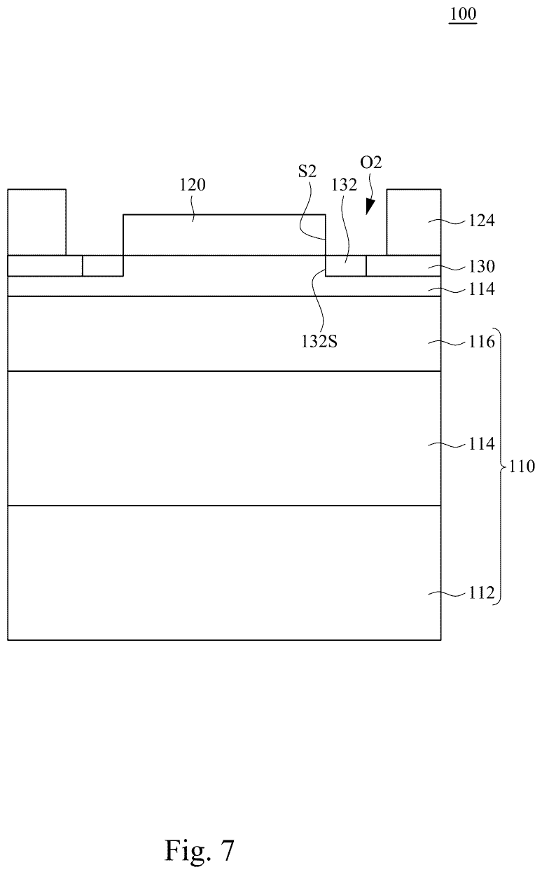

Referring to FIG. 7, a second implantation process is performed to form a second implant region 132 in the substrate 110 through the first mask 120 and the second spacer 124. By removing a portion of the first mask 120, the second implant region 132 is self-aligned with the first implant region 130. As shown, the second sidewall S2 of the second opening O2 is aligned with the sidewall 132S of the second implant region 132. In other words, the difference between the first width W1 and the second width W2 of the first mask 120 is approximately equal to the width of the second implant region 132. The second implant region 132 is formed in the lightly doped layer 114 of the substrate 110 exposed by the first mask 120 and the second spacer 124. The bottom surface of the second implant region 132 is located in the lightly doped layer 114 and does not contact the current spreading layer 116. In some embodiments, the second implant region 132 has the first dopant type. In some embodiments, the second implant region 132 may be an N+region.

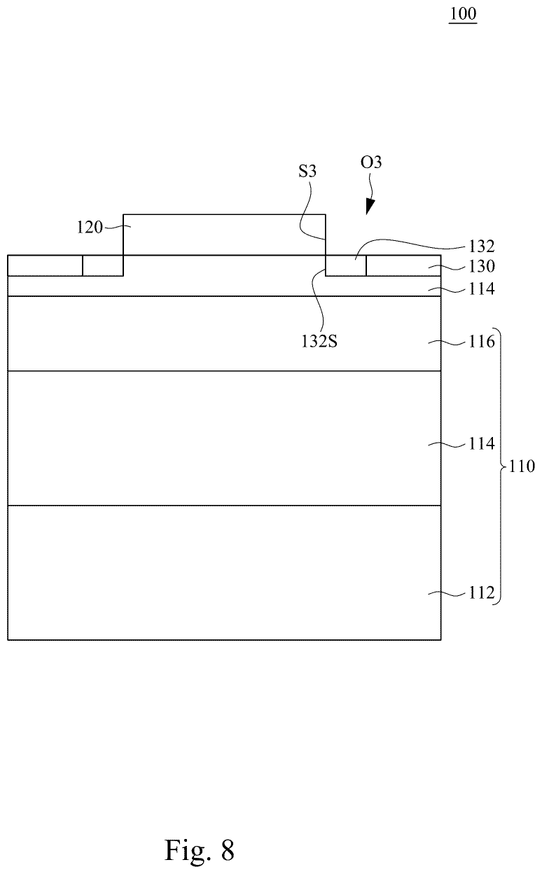

Referring to FIG. 8, a third wet etching process is performed using a third etchant to remove the second spacer 124. After the second spacer 124 is removed, the top surface of the first implant region 130 is exposed. As shown in the figure, the second opening O2 is expanded into the third opening O3, and the third sidewall S3 of the third opening O3 close to the first mask 120 is still aligned with the sidewall 132S of the second implant region 132. In some embodiments, when the second spacer 124 is silicon oxide, the third etchant is a buffered oxide etchant (BOE), which includes hydrogen fluoride (HF) and ammonium fluoride (NH₄F). In some embodiments, the third wet etching process is performed at a third temperature, and the third temperature is about 25° C. The third etchant has an etch rate of 20 to 50 nm per minute for the second spacer 124.

In some embodiments, when the materials of the first spacer 122 and the second spacer 124 are exchanged, the etching environments used are also exchanged. In detail, when the first spacer 122 is silicon oxide, the first etchant is a buffered oxide layer etchant, and the first temperature is about 25° C. When the second spacer 124 is polysilicon, the third etchant is tetramethylammonium hydroxide, and the third temperature is in a temperature range of 60° C. to 80° C.

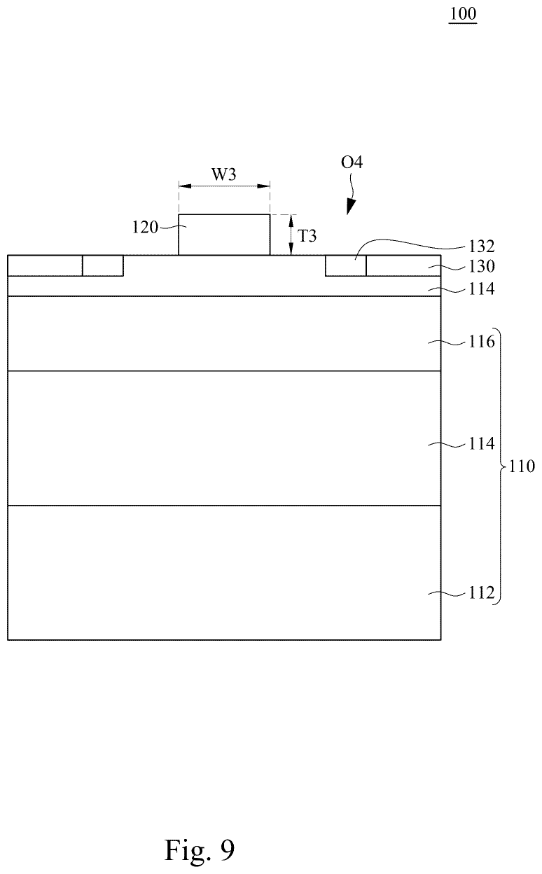

Referring to FIG. 9, a fourth wet etching process is performed with a fourth etchant to remove the second portion of the first mask 120 and expose a portion of the top surface of the lightly doped layer 114 of the substrate 110. As shown in the figure, the third opening O3 is expanded into the fourth opening O4. At this time, the first mask 120 has a third thickness T3 and a third width W3. The third thickness T3 is smaller than the second thickness T2, and the third width W3 is smaller than the second width W2. In some embodiments, the fourth etchant is the same as the second etchant. In some embodiments, the etching environment of the fourth wet etching process is the same as that of the second wet etching process. In some embodiments, the fourth etchant includes phosphoric acid (H3PO4). In some embodiments, the fourth wet etching process is performed at a temperature range of 150° C. to 180° C. The fourth etchant has a slower etch rate of 20 to 50 nm per minute for the first mask 120.

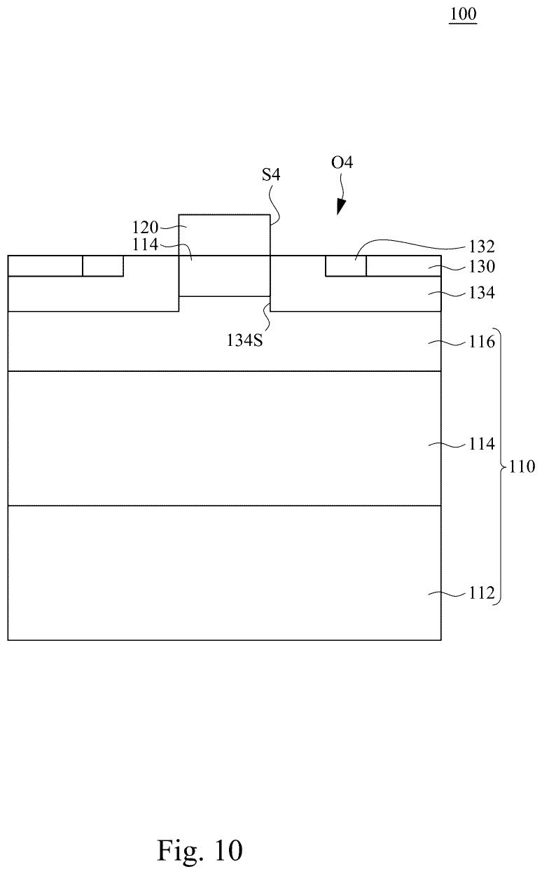

Referring to FIG. 10, a third implantation process is performed to form a first well region 134 in the substrate 110 through the first mask 120. By removing a portion of the first mask 120, the first well region 134 is self-aligned with the second implant region 132. As shown, the fourth sidewall S4 of the fourth opening O4 is aligned with the sidewall 134S of the first well region 134. In other words, the difference between the second width W2 and the third width W3 of the first mask 120 is approximately equal to the width of the first well region 134 at the top surface of the substrate 110. The first well region 134 is formed in the lightly doped layer 114 and the current spreading layer 116 of the substrate 110. That is, the bottom surface of the first well region 134 is located on the current spreading layer 116. In some embodiments, the first well region 134 has a second dopant type. In some embodiments, the first well region 134 is a P-type well region (p-well). By removing the first mask 120 in stages through precise wet etching, two self-aligned ion implantations can be performed with one mask, thereby simplifying the process of forming the mask and reducing ion implantation errors caused by mask deviation.

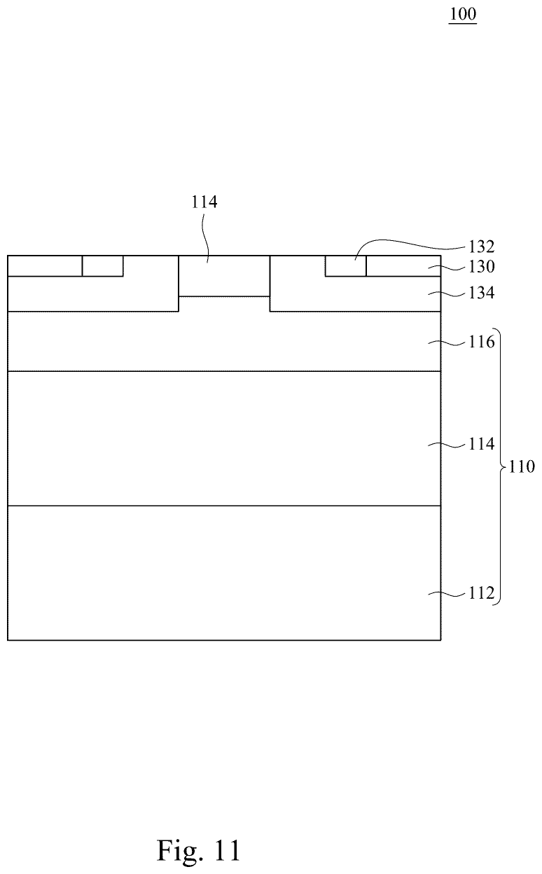

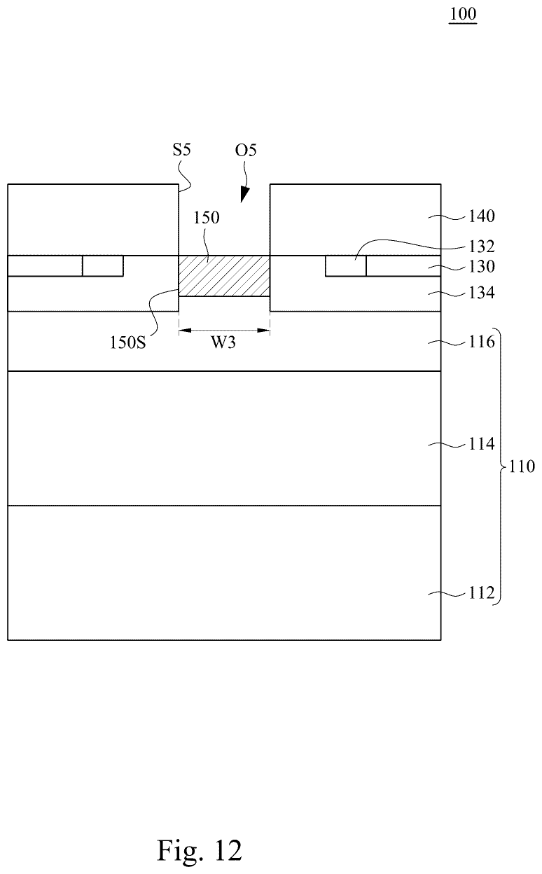

Referring to FIG. 11, the first mask 120 is removed and the top surface of the substrate 110 is exposed. In detail, the top surfaces of the lightly doped layer 114, the first implanted region 130, the second implanted region 132, and the first well region 134 are exposed. The first mask 120 may be removed using a suitable etching process. Referring to FIG. 12, a second mask 140 is formed to expose the top surface of the lightly doped layer 114 of the substrate 110. In detail, the second mask 140 covers the top surfaces of the first implant region 130, the second implant region 132 and the first well region 134, and the fifth opening O5 of the second mask 140 exposes the top surface of the lightly doped layer 114. Next, a fourth implantation process is performed on the lightly doped layer 114 to form the transistor 150. In some embodiments, the transistor 150 may be a junction field effect transistor (JFET). In some embodiments, transistor 150 has a first dopant type. In some embodiments, the fifth sidewall S5 of the fifth opening O5 is aligned with the sidewall 150S of the transistor 150. In some embodiments, the width of the transistor 150 is a third width W3. In detail, the width of the transistor 150 is the same as the width of the first mask 120 after the second wet etching process is performed.

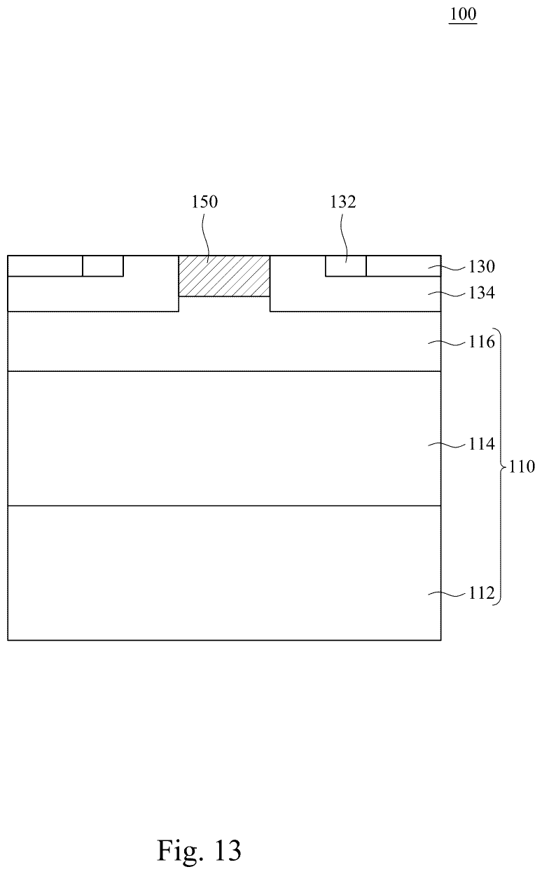

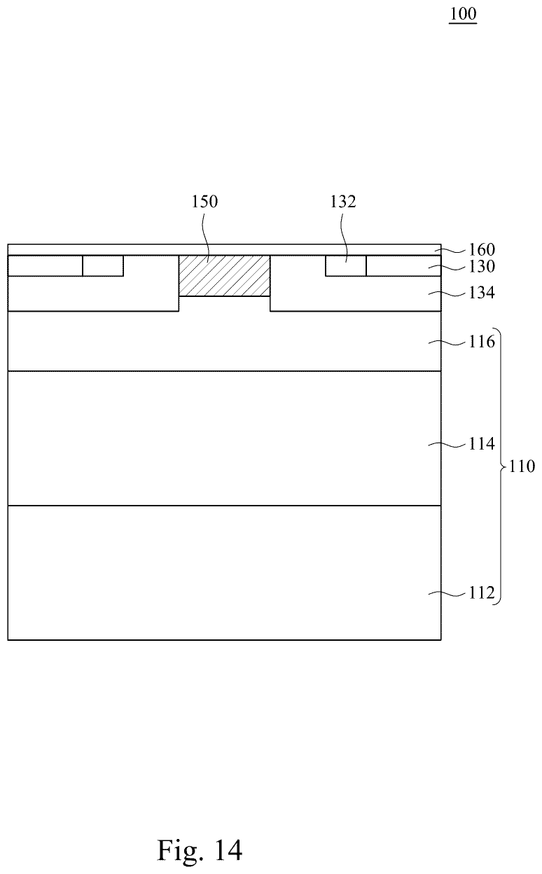

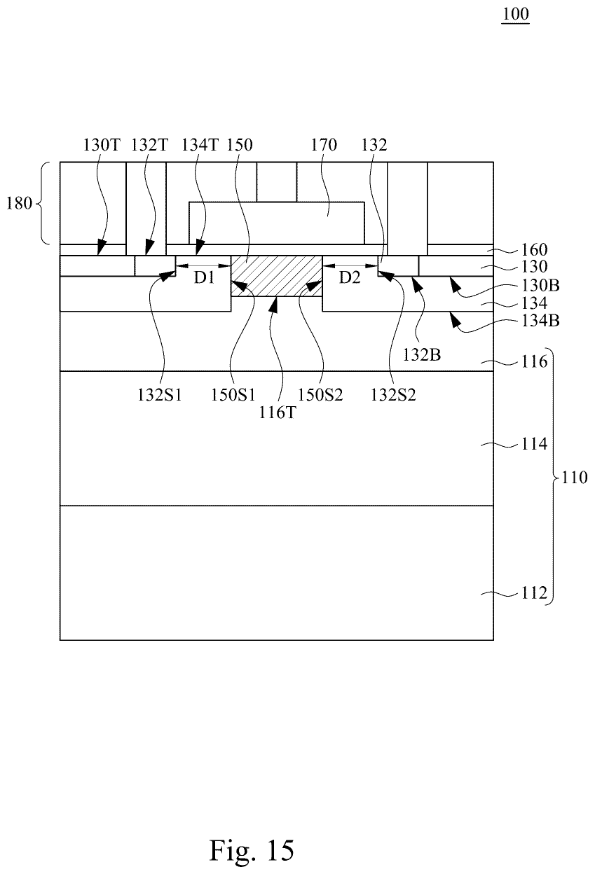

Referring to FIG. 13, the second mask 140 is removed and the top surface of the substrate 110 is exposed. The second mask 140 may be removed using a suitable etching process. Referring to FIG. 14, a high temperature annealing process is performed on the top surface of the substrate 110 to form a gate oxide layer 160. In some embodiments, the gate oxide layer 160 may be formed using a suitable deposition process. Referring to FIG. 15, a gate 170 is formed on the gate oxide layer 160, and a back-end process component 180 is formed on the gate 170.

As shown in FIG. 15, the semiconductor structure 100 includes a substrate 110, a first implant region 130, a second implant region 132 and a first well region 134. The substrate 110 includes a heavily doped layer 112, a lightly doped layer 114, and a current spreading layer 116. The lightly doped layer 114 is located between the heavily doped layer 112 and the current spreading layer 116. The first implant region 130, the second implant region 132 and the first well region 134 are located on the current spreading layer 116. The first implant region 130 and the second implant region 132 are located in the first well region 134. The bottom surface 134B of the first well region 134 is lower than the top surface 116T of the current spreading layer 116. The bottom surface 130B of first implant region 130 is coplanar with the bottom surface 132B of second implant region 132. The bottom surface 130B of the first implant region 130 and the bottom surface 132B of the second implant region 132 are higher than the bottom surface 134B of the first well region 134. The top surface 130T of the first implant region 130, the top surface 132T of the second implant region 132, and the top surface 134T of the first well region 134 are coplanar.

The semiconductor structure 100 includes a transistor 150, a gate oxide layer 160 and a gate 170. The transistor 150 is located between the first well regions 134 and on the top surface 116T of the current spreading layer 116. The transistor 150 has a first sidewall 150S1 and a second sidewall 150S2. A distance between the first sidewall 150S1 of the transistor 150 and the first sidewall 132S1 of the second implant region 132 is a first distance D1. A distance between the second sidewall 150S2 of the transistor 150 and the second sidewall 132S2 of the second implant region 132 is a second distance D2. Since two self-aligned implantations are performed using a single mask, the first distance D1 is equal to the second distance D2 without causing an offset. The gate oxide layer 160 is located above the top surface 130T of the first implanted region 130, the top surface 132T of the second implanted region 132, the top surface 134T of the first well region 134, and the top surface of the transistor 150. The gate 170 is located above the gate oxide layer 160. The semiconductor structure 100 includes a back-end processing component 180. The back-end process component 180 is located above the gate oxide layer 160 and the gate 170.

The disclosed method removes the first mask in stages through a precise wet etching process, and can perform two self-aligned ion implantations with one mask, thereby simplifying the process of forming the mask and reducing the ion implantation error caused by the offset of forming multiple masks.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A manufacturing method of semiconductor structure, comprising:
providing a substrate;
forming a first mask on the substrate;
performing a first implantation process with the first mask to form a first implant region in the substrate;
forming a first spacer on the sidewall of the first mask, and forming a second spacer on the sidewall of the first spacer to cover the first implant region, wherein the first mask, the first spacer and the second spacer are formed of different materials;
removing the first spacer;
removing a first portion of the first mask;
performing a second implantation process with the first mask and the second spacer to form a second implant region in the substrate, such that the second implant region is self-aligned with the first implant region;
removing the second spacer;
removing a second portion of the first mask; and
performing a third implant process with the first mask to form a first well region in the substrate, such that the first well region is self-aligned with the second implant region.

2. The method of claim 1, wherein a first wet etching process is performed using a first etchant to remove the first spacer, wherein the first spacer comprises polysilicon and the first etchant comprises tetramethylammonium hydroxide;
a second wet etching process is performed using a second etchant to remove the first portion of the first mask, wherein the first mask comprises silicon nitride and the second etchant comprises phosphoric acid;
a third wet etching process is performed using a third etchant to remove the second spacer, wherein the second spacer comprises silicon oxide, and the third etchant comprises hydrofluoric acid and ammonium fluoride; and
a fourth wet etching process is performed using a fourth etchant to remove the second portion of the first mask, and the fourth etchant includes phosphoric acid.

3. The method of claim 2, wherein the substrate has a heavily doped layer, a lightly doped layer located on the heavily doped layer, and a current spreading layer located within the lightly doped layer, and the first mask covers the lightly doped layer.

4. The method of claim 3, wherein after performing the second wet etching process using the second etchant, the first mask and the second spacer together expose a portion of the first implant region and a portion of the lightly doped layer adjacent to the first implant region.

5. The method of claim 3, wherein after performing the fourth wet etching process using the fourth etchant, the first mask exposes the first implant region, the second implant region, and a portion of the lightly doped layer adjacent to the second implanted region.

6. The method of claim 3, further comprising:
after forming the first well region, the first mask is removed, and a second mask is formed to cover the first implant region, the second implant region and the first well region, and the second mask is formed to expose the lightly doped layer.

7. The method of claim 6, further comprising:
performing a fourth implantation process with the second mask to form a transistor in the lightly doped layer of the substrate;
performing a thermal annealing process to form a gate oxide layer on the substrate; and
a gate is formed on the gate oxide layer.

8. A manufacturing method of semiconductor structure, comprising:
providing a substrate;
forming a first mask on the substrate;
performing a first implantation process with the first mask to form a first implant region in the substrate;
forming a first spacer and a second spacer on the sidewall of the first mask, wherein the first spacer is located between the first mask and the second spacer, and the first spacer and the second spacer cover the first implant region, wherein the first mask, the first spacer, and the second spacer are formed of different materials;
removing the first spacer to form a first opening, wherein a sidewall of the first implant region is aligned with a first sidewall of the first opening;
removing a first portion of the first mask to expand the first opening into a second opening;
performing a second implantation process with the first mask and the second spacer to form a second implant region in the substrate, wherein a sidewall of the second implant region is aligned with a second sidewall of the second opening;
removing the second spacer to expand the second opening into a third opening, wherein the sidewall of the second implant region is aligned with a third sidewall of the third opening;
removing a second portion of the first mask to expand the third opening into a fourth opening; and
performing a third implantation process with the first mask to form a first well region in the substrate, wherein a sidewall of the first well region is aligned with a fourth sidewall of the fourth opening.

9. The method of claim 8, wherein the substrate and the first implantation process include different dopant types.

10. The method of claim 8, wherein the first implantation process and the second implantation process include different dopant types.

11. The method of claim 8, wherein the first implantation process and the third implantation process include the same dopant type.

12. The method of claim 8, wherein before performing the first implantation process, the first mask has a first thickness, and the first thickness is greater than 5 microns.

13. A semiconductor structure, comprising:
a substrate has a current spreading layer;
a transistor located on the current spreading layer, having a first sidewall and a second sidewall;
a first well region located on the current spreading layer and respectively contacting the first sidewall and the second sidewall of the transistor, wherein a bottom surface of the first well region is lower than a top surface of the current spreading layer;
a first implant region located in the first well region; and
a second implant region located in the first well region and between the first implant region and the transistor, the second implant region has a first sidewall and a second sidewall, wherein a first distance is between the first sidewall of the second implant region and the first sidewall of the transistor, and a second distance is between the second sidewall of the second implant region and the second sidewall of the transistor, and the first distance is equal to the second distance.

14. The semiconductor structure of claim 13, wherein the substrate further comprises:
a heavily doped layer located below the current spreading layer; and
a lightly doped layer located between the current spreading layer and the heavily doped layer.

15. The semiconductor structure of claim 13, further comprising:
a gate located on the transistor; and
a gate oxide located between the transistor and the gate.

16. The semiconductor structure of claim 13, wherein a bottom surface of the first implant region and a bottom surface of the second implant region are higher than the bottom surface of the first well region.

17. The semiconductor structure of claim 13, wherein a top surface of the first implant region and a top surface of the second implant region and a top surface of the first well region are coplanar.
